(19) United States
(12) Patent Application Publication
(10) Pub. No.: US 2006/0068507 A1
(43) Pub. Date: Mar. 30, 2006

(54) Methods of forming a material film, methods of forming a capacitor, and methods of forming a semiconductor memory device using the same

(76) Inventors: Wenxu Xianyu, Yongin-si (KR); Takashi Noguchi, Seongnam-si (KR); Hans S. Cho, Seoul (KR); Jang-Yeon Kwon, Seongnam-si (KR); Huaxiang Yin, Yongin-si (KR)

Correspondence Address: HARNESS, DICKEY & PIERCE, P.L.C., P.O. BOX 8910, RESTON, VA, 20195, US

(21) Appl. No.: 11/233,363

(22) Filed: Sep. 23, 2005

(30) Foreign Application Priority Data
Sep. 24, 2004 (KR) 10-2004-0077152

(51) Int. Cl. H01L 21/00; H01L 21/8242

(52) U.S. Cl. 438/3; 438/253; 438/396

(57) ABSTRACT

A method of forming a material (e.g., ferroelectric) film, a method of manufacturing a capacitor, and a method of forming a semiconductor memory device using the method of forming the (e.g., ferroelectric) film are provided. Pursuant to an example embodiment of the present invention, a method of forming a ferroelectric film includes preparing a substrate, depositing an amorphous ferroelectric film on the substrate, and crystallizing the amorphous ferroelectric film by irradiating it with a laser beam. According to still another example embodiment of the present invention, a method of forming a ferroelectric film may reduce the thermal damage to other elements because the ferroelectric film may be formed at a temperature lower than about 500° C. to about 550°C.

### PRIORITY STATEMENT

This application claims priority under 35 U.S.C. § 119 of Korean Patent Application No. 10-2004-0077152, filed on Sep. 24, 2004, in the Korean Intellectual Property Office (KIPO), the entire contents of which are incorporated herein by reference.

### BACKGROUND OF THE INVENTION

1. Field of the Invention

Example embodiments of the present invention relate to a method of forming a material film, a method of manufacturing a capacitor using the material film, and a method of manufacturing a device using the material film. Various embodiments of the present invention relate to a method of forming a ferroelectric film and to methods of manufacturing a capacitor and/or a semiconductor memory device using, for example, the method of forming the ferroelectric film.

2. Description of the Related Art

Ferroelectric Random Access Memories (FRAMs) and Magnetic Random Access Memories (MRAMs) are examples of nonvolatile memories which may be alternatives to flash memories.

A FRAM includes, but is not limited to, a transistor and a capacitor using a ferroelectric film as a dielectric and a MRAM includes, but is not limited to, a magnetic tunnel junction layer used in place of a capacitor as a data recording material.

A FRAM may be manufactured using at least two processes: a process for forming a field effect transistor (FET) on a substrate and a process for forming a ferroelectric capacitor to be connected to the FET on a resultant structure in which the FET may be formed. A ferroelectric film may be a dielectric having a greater dielectric constant than that of a dielectric film in, for example, a conventional capacitor. However, in comparison to the dielectric film, the ferroelectric film appears to exhibit greater etch resistance. Accordingly, etching the ferroelectric film should be comparatively more difficult.

To form a ferroelectric film, a variety of methods, including (but not limited to), for example, a chemical solution deposition (CSD) method has been utilized. The CSD method may be simple and/or permit easy control of components. However, the CSD method also may have some drawbacks. For example, step coverage may be poor and materials that constitute the FRAM may be damaged thermally when a ferroelectric film is formed, for example, at a temperature greater than 600° C.

### SUMMARY

Example embodiments of the present invention provide a method of forming a ferroelectric film so that potential thermal damage to other FRAM components may be reduced during formation of the ferroelectric film.

An example embodiment of the present invention provides a method of manufacturing a ferroelectric film.

An example embodiment of the present invention provides a method of manufacturing a capacitor of a semiconductor device using, for example, a method of forming a ferroelectric film.

Another example embodiment of the present invention provides a method of manufacturing a semiconductor device using, for example, a method of manufacturing a capacitor or a method of forming a ferroelectric film.

An example embodiment of the present invention provides at least one method of forming a ferroelectric film, the method comprising preparing a substrate suitable for depositing the ferroelectric film, depositing an amorphous ferroelectric film on the substrate, and crystallizing the amorphous ferroelectric film. The crystallizing may be accomplished, for example, by irradiating the amorphous ferroelectric film. For irradiating, a laser beam may be used.

According to an example embodiment of the present invention, the depositing of the amorphous ferroelectric film on the substrate may include coating the substrate with a chemical solution that includes a ferroelectric film source, solidifying the chemical solution to form a resultant product, and pre-annealing the resultant product. The pre-annealing may be performed at a temperature in a range from about 500 to about 550° C.

According to an example embodiment of the present invention, the laser beam may be at least one of a XeCl excimer laser beam and a KrF excimer laser beam, and the irradiation with the laser beam may be performed at a substrate temperature lower than about 500° C. under an oxygen and/or nitrogen atmosphere, for example. Pursuant to another example embodiment of the present invention, the chemical solution may be solidified by baking at about 300° C. for about 5 minutes. Also, the coating of the chemical solution and the solidifying of the chemical solution may be repeated, as necessary, according to another example embodiment of the present invention.

Another example embodiment of the present invention provides a method of manufacturing a capacitor, the method comprising forming a lower electrode, forming an amorphous (e.g., ferroelectric) film on the lower electrode, crystallizing the amorphous (e.g., ferroelectric) film by irradiating the amorphous (e.g., ferroelectric) film with a laser beam; and forming an upper electrode on the crystallized (e.g., ferroelectric) film.

In an example embodiment of the present invention, forming an amorphous ferroelectric film on the lower electrode may include coating a chemical solution that includes a ferroelectric film source on the substrate, solidifying the chemical solution to form a solidified resultant product, and pre-annealing the solidified resultant product.

In another example embodiment of the present invention, these same coating (e.g., of the chemical solution), irradiating (e.g., with a laser beam), and, pre-annealing may be conducted in conjunction with a method of forming a material (e.g., ferroelectric) film.

When forming a ferroelectric film, the ferroelectric film may be at least one selected from the group consisting of a PZT film, a SBT film, a BLT film, and a BNT film. Other suitable films may be used.

Another example embodiment of the present invention provides, for example, a method of manufacturing a semiconductor memory device which includes a substrate (e.g., transparent) suitable for use in a low temperature (e.g., lower than about 600° C., 550° C. or 500° C., for example, about 400° C. or about 300° C.) process, a transistor (e.g., TFT) used in a similar low temperature poly silicon process, and a capacitor. Such a method may comprise, for example, forming a lower electrode to be connected to a TFT, forming an amorphous ferroelectric film on the lower electrode, crystallizing the amorphous ferroelectric film by irradiating the amorphous ferroelectric film with a laser beam, and forming an upper electrode on the crystallized ferroelectric film.

According to another example embodiment of the present invention, for example, forming the amorphous ferroelectric film on the lower electrode and of forming the upper electrode on the crystallized ferroelectric film may be the same as used in the method of manufacturing a capacitor and/or used in the method of forming a semiconductor memory device.

Another example embodiment of the present invention provides, for example, a method of forming a material film, the method including performing a chemical solution deposition of an amorphous material film at a temperature lower than 550° C. and irradiating the amorphous material film by irradiating with a laser beam at a temperature lower than 550° C. to form a crystalline material film.

Another example embodiment of the present invention provides, for example, a method, wherein the amorphous material film and the crystalline material film are ferroelectric films.

Another example embodiment of the present invention provides, for example, a method of manufacturing a capacitor including forming the crystallized ferroelectric film on a lower electrode and forming an upper electrode on the crystallized ferroelectric film.

Another example embodiment of the present invention provides, for example, a method of manufacturing a semiconductor memory device including forming the crystallized ferroelectric film according to claim 16 on a lower electrode connected a TFT and forming an upper electrode on the crystallized ferroelectric film.

Another example embodiment of the present invention provides, for example, a capacitor including a substrate, at least one lower electrode formed on the substrate, a crystallized ferroelectric film formed on the at least one lower electrode and the substrate, and at least one upper electrode, formed on crystallized ferroelectric film, orthogonal to the at least one lower electrode.

Another example embodiment of the present invention provides, for example, a semiconductor memory device including a capacitor and a TFT, connected to the at least one lower electrode.

When the material film is a ferroelectric film, it may be formed to have a thickness less than about 250 nm (e.g., 240 nm, 230 nm, 220 nm, 210 nm, 200 nm, 180 nm, 160 nm, 150 nm, and 100 nm). It should be noted that whatever thickness is used, the thickness should be suitable for its intended use.

Another example embodiment of the present invention relates to forming a thin film transistor (TFT) which comprises forming a buffer layer on a transparent substrate, forming an amorphous silicon layer on the buffer layer, crystallizing the amorphous silicon layer into a polycrystalline silicon layer, forming a polycrystalline silicon layer island by patterning the polycrystalline silicon layer, forming a gate stack on a region of the polycrystalline silicon layer island, doping an exposed region of the polycrystalline silicon layer island, and activating the doped region of the polycrystalline silicon layer island. If suitable, a non-transparent substrate and/or a non-silicon amorphous layer may be used where appropriate.

According to an example embodiment of the present invention, the doped region of the polycrystalline silicon layer island may be activated by irradiating the polycrystalline silicon layer island with an excimer laser.

According to yet another embodiment of the present invention, for example, a crystallized ferroelectric film may be formed at a temperature lower than about 500° C. by combining a CSD method with a laser irradiation method. Therefore, by such example embodiments of the present invention, thermal damage to other elements may be reduced when forming the ferroelectric film. Also, the ferroelectric film crystallization process of an example embodiment may be selectively performed using a laser. By doing so, the crystallization process of the ferroelectric film may lend itself for use in a high integration process and may make mass production more readily achievable or possible.

### BRIEF DESCRIPTION OF THE DRAWINGS

Example embodiments of the present invention will become more apparent by describing in detail various examples thereof with reference to the attached drawings. FIGS. 1-15 represent non-limiting examples, embodiments and/or intermediates of the present invention as described herein.

FIGS. 1 through 4 are cross-sectional views illustrating a method of forming a ferroelectric film according to an example embodiment of the present invention.

FIG. 5 is a flowchart relating to the method of forming a ferroelectric film depicted in an example embodiment of FIGS. 1 through 4 of the present invention.

FIG. 6 is a graph showing a crystal analysis result with respect to, for example, a PZT film formed using the method of forming a ferroelectric film depicted in an example embodiment of FIGS. 1 through 4 of the present invention.

FIGS. 7 and 8 are cross-sectional views illustrating a method of manufacturing a capacitor using a method of forming a ferroelectric film depicted in example embodiments of the present invention.

FIG. 9 is a plan view illustrating an example of a cell array of a capacitor in which lower and upper electrodes are included in a crossed shape pursuant to an example embodiment of the present invention.

FIGS. 10 through 15 are cross-sectional views illustrating a method of manufacturing a semiconductor device according to an example embodiment of the present invention, using a method of manufacturing a capacitor and/or a method of forming a ferroelectric film depicted in example embodiments of the present invention.

### DETAILED DESCRIPTION OF EXAMPLE EMBODIMENTS OF THE INVENTION

Various example embodiments of the present invention will now be described more fully with reference to the accompanying drawings in which some example embodiments of the invention are shown. In the drawings, the thicknesses of layers and regions are exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

A method of forming a ferroelectric film according to an example embodiment of the present invention will now be described.

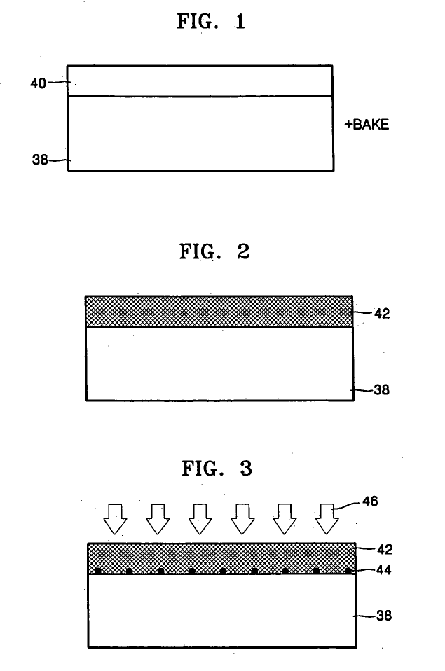

Referring to the example embodiment of FIG. 1 of the present invention, for example, a substrate 38 appropriate for depositing a ferroelectric film may be prepared and a chemical solution layer 40 that includes a ferroelectric film source may be coated on the substrate 38. The chemical solution layer 40 may be coated to a desired thickness, for example, from about 30 nm to about 100 nm. The chemical solution layer 40 may include a source for forming at least one film selected from the group consisting of a PZT film, a SBT film, a BLT film, and a BNT film. According to an example embodiment of the present invention, the chemical solution layer 40 may be coated using spin coating or any other suitable coating method.

The chemical solution layer 40 may be solidified by baking the resultant product (e.g., substrate 38 coated with chemical solution layer 40). The bake may be performed at a temperature of about 300° C. for about 5 minutes. Baking temperatures and times may be varied according to the substrate, the chemical solution layer, and the kind and thickness of the chemical solution layer 40 used. Referring to FIG. 2, for example, an amorphous ferroelectric film 42 may be formed on the substrate 38.

Pursuant to one or more example embodiments of the present invention, the chemical solution layer 40 may be formed to a desired thickness in one single coating process, but it may also be formed in two or more coating processes. For example, if the overall thickness of the chemical solution layer 40 is intended to be about 40 nm, the chemical solution layer 40 may be formed in two coating processes by coating successively two layers of 20 nm each or by some suitably applicable variation thereof.

In an example embodiment where the chemical solution layer 40 may be formed in two or more coating processes, intervening baking may also be performed after every coating. The process for forming the chemical solution layer 40 and the process for baking may be repeated until a desired thickness of the chemical solution layer 40 is obtained.

The substrate 38 on which the amorphous ferroelectric film 42 may be formed may be pre-annealed. The pre-annealing may be performed at a temperature in a range from about 500 to about 550° C. for about 30 minutes under an oxygen atmosphere. However, a nitrogen atmosphere and/or other suitable atmosphere may be used.

As depicted in FIG. 3, an irradiating laser beam 46 having a desired energy density may be applied to the pre-annealed amorphous ferroelectric film 42. The energy density of the laser beam 46 may be from about 50 mJ/cm² to about 500 mJ/cm². The irradiation by laser beam 46 may be performed using a XeCl excimer laser, but a KrF excimer laser may also be used. Other suitable laser sources may also be used. When a XeCl excimer laser is used, the irradiation of the laser beam 46 may be performed under an oxygen atmosphere or a nitrogen atmosphere. Other suitable atmospheres may also be used. In an example embodiment of the present invention, the substrate 38 may be maintained at a temperature in a range of from about 400 to about 500° C. If the energy density of the laser beam 46 is appropriate, the irradiation by laser beam 46 may only need to be used once, but, if the energy density of the laser beam 46 is not appropriate, irradiation with the laser beam 46 may be performed two or more times, as needed.

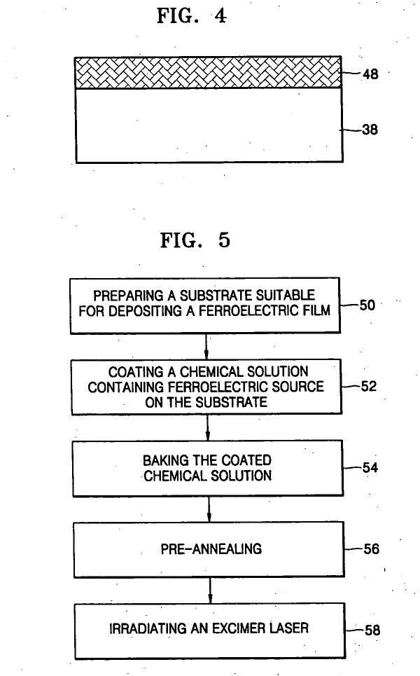

Referring to FIG. 3, as a result of melting the pre-annealed amorphous ferroelectric film 42 caused by the irradiation of laser beam 46, seeds 44 for growing crystals may be formed on a part (e.g., bottom) of the amorphous ferroelectric film 42. That is, for example, on a surface of the substrate 38. Additional crystals may then be formed from the seeds 44 and extended across a surface of the amorphous ferroelectric film 42. As a result, as depicted in FIG. 4, a crystallized material (e.g., ferroelectric) film 48 may be formed on the substrate 38.

Referring to FIG. 5, an example embodiment of the present invention may be summarized, for example, by:

50: preparing a substrate suitable for depositing a material (e.g., ferroelectric) film;

52: coating a chemical solution for forming an amorphous (e.g. ferroelectric) film on the substrate;

54: solidifying the coated chemical solution for forming the amorphous (e.g. ferroelectric) film by baking the chemical solution;

56: pre-annealing the baked amorphous (e.g. ferroelectric) film; and

58: irradiating the pre-annealed amorphous (e.g., ferroelectric) film with a laser.

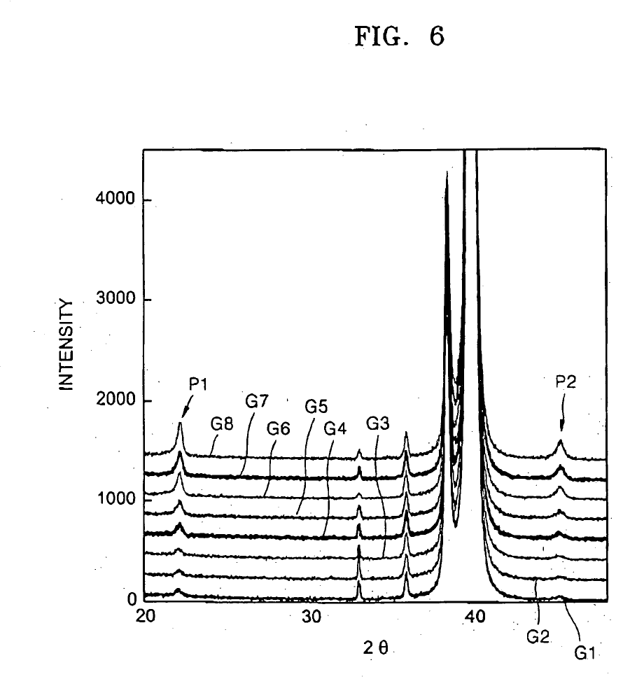

FIG. 6 illustrates an X-ray diffraction pattern with respect to a PZT film formed using a method according to an example embodiment of the present invention.

In FIG. 6, G1 represents an X-ray diffraction pattern of a PZT film before irradiation. G2 represents an X-ray diffraction pattern of a PZT film after irradiation 100 times with a laser beam having an energy density of 300 mJ/cm². G3 represents an X-ray diffraction pattern of a PZT film after irradiation 100 times with a laser beam having an energy density of 325 mJ/cm². G4 represents an X-ray diffraction pattern of a PZT film after irradiation 100 times with a laser beam having an energy density of 350 mJ/cm². G5 represents an X-ray diffraction pattern of a PZT film after irradiation 100 times with a laser beam having an energy density of 375 mJ/cm². G6 represents an X-ray diffraction pattern of a PZT film after irradiation 50 times with a laser beam having an energy density of 400 mJ/cm². G7 represents an X-ray diffraction pattern of a PZT film after irradiation 50 times with a laser beam having an energy density of 425 mJ/cm². G8 represents an X-ray diffraction pattern of a PZT film after irradiation 50 times with a laser beam having an energy density of 450 mJ/cm².

In FIG. 6, reference numeral P1 represents a first peak group which is a group of peaks with respect to a (100) crystal face of the PZT film, and reference numeral P2 represents a second peak group which is a group of peaks with respect to a (200) crystal face of the PZT film.

Regarding the peaks in the first peak group P1, the height of peaks in the graphs G2 through G8 is higher than the height of the peak in the graph G1. The same is true for the peaks in the second peak group P2.

Also, regarding the first peak group P1, the height of the peaks in the graphs G2 through G8 is greater when the energy density of the laser beam irradiating the PZT film is higher.

Various additional non-limiting examples of a ferroelectric film formed according to one or more embodiments of the present invention are described in the context of manufacturing a capacitor.

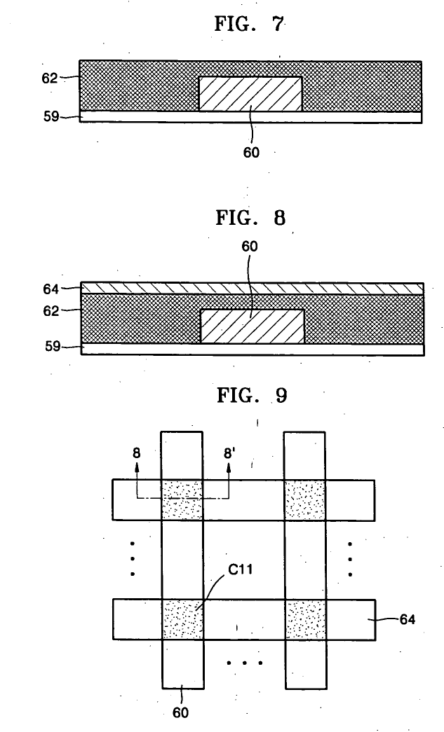

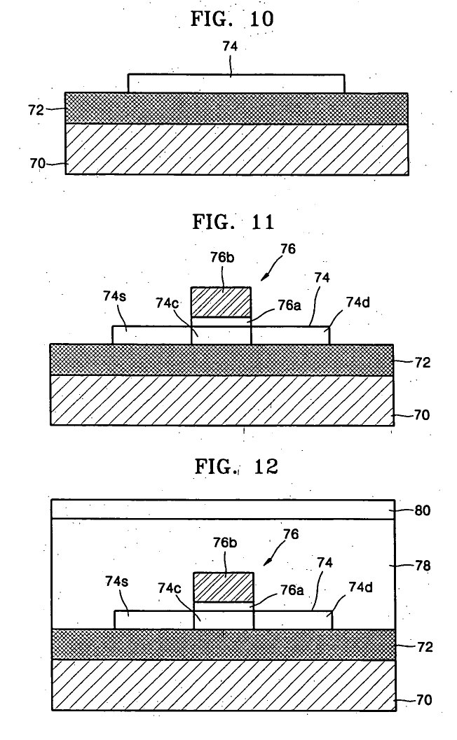

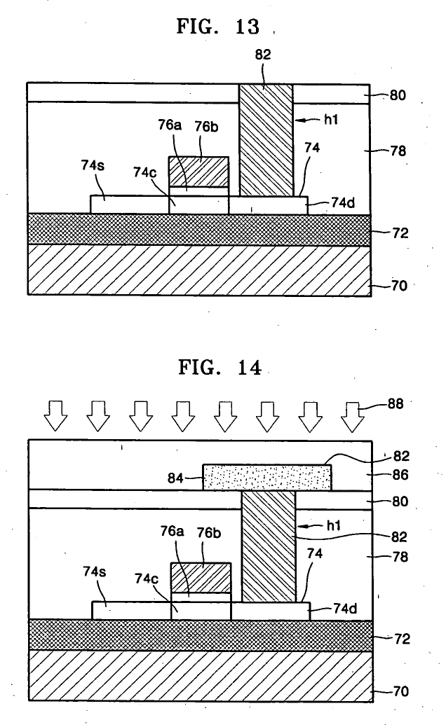

A method of manufacturing a capacitor that includes a ferroelectric film formed according to an example embodiment of the present invention will now be described with reference to FIGS. 7 and 8 of the present invention.

Referring to FIG. 7, a lower electrode 60 in a strip shape may be formed on a base material film 59, and a dielectric film 62 covering the lower electrode 60 may be formed on the base material film 59. Other suitable shapes for the lower electrode 60 may be used. The dielectric film 62 may be formed of a ferroelectric film selected from the group consisting of a PZT film, a SBT film, a BLT film, and a BNT film. For example, the dielectric film 62 may be formed by an example embodiment of the present invention. When a ferroelectric film is used as the dielectric film 62, the lower electrode 60 may be formed of an etch-resistant metal, for example, Pt or Ru, which withstands etching when the dielectric film 62 is/may be etched.

Referring to FIG. 8, an upper electrode 64 may be formed on the dielectric film 62. The upper electrode 64 may be formed in one or more strips horizontally oriented across one or more lower electrodes 60 as shown in FIG. 9 discussed below. The upper electrode 64 may be formed of a metal, for example, Pt, having superior interface characteristics with the dielectric film 62. Other suitable upper electrode materials/metals may be used.

FIG. 9 depicts a cross-sectional view taken along line 8-8′. In FIG. 9, a capacitor C11 may be formed where the lower electrode 60 and the upper electrode 64 cross each other. Other suitable patterns of the lower electrode 60 and the upper electrode 64 may be used. The dielectric film 62 and the base material film 59, though present, are not shown in FIG. 9 for convenience.

According to another example embodiment of the present invention, a method of manufacturing a semiconductor memory device that includes a capacitor formed according to an example embodiment of the present invention is described below with reference to FIGS. 10 through 15 of the present invention.

Referring to FIG. 10, a first buffer layer 72 may be formed on a substrate 70. The substrate 70 may be, for example, a transparent substrate, e.g., a glass substrate, suitable for a low temperature (e.g., from about 300 to about 500° C., 550° C. or 600° C.) process. The first buffer layer 72 may be a silicon oxide film. A thin film transistor (TFT) may be formed on the first buffer layer 72 by using a low temperature polycrystalline silicon process (LTPS). Other suitable substrates, first buffer layers and low temperature polycrystalline processes may be used.

A polycrystalline silicon layer 74 may be formed by crystallizing an amorphous silicon layer (not shown) after forming the amorphous silicon layer on the substrate 70. The crystallization process of the amorphous silicon layer may be performed at a low temperature (e.g., from about 300° C. to about 500° C., 550° C. or 600° C.) using a laser (for example, an excimer laser). After forming the polycrystalline silicon layer 74, as depicted in FIG. 11, a gate stack 76 (e.g., 76a and 76b) may be formed on a desired region of the polycrystalline silicon layer 74. The gate stack 76 may include a gate insulating film 76a and a gate electrode 76b that are sequentially stacked as depicted in FIG. 11.

The gate insulating film 76a may be formed of a silicon oxide film, but may also be formed of a dielectric film, e.g., a high-K film, having a greater dielectric constant than the dielectric constant of a silicon oxide film. Other suitable gate insulating film materials may be used.

The gate electrode 76b may be formed of a metal, for example, Al, or a silicide material. Other suitable materials/metals for the gate electrode may be used.

A protection film (not shown) may further be included on the gate electrode 76b. After forming the gate stack 76, a conductive dopant may be doped on an exposed region of the polycrystalline silicon layer 74 and the doped dopant may be activated. The activation of the doped dopant may be performed at a low temperature (e.g., from about 300° C. to about 500° C., 550° C., or 600° C.) using a laser (for example, an excimer laser). In this way, source and drain regions 74s and 74d may be formed on the polycrystalline silicon layer 74. A portion of the polycrystalline silicon layer 74 which may be formed under the gate stack 76 may be depicted as a channel region 74c that connects the source region 74s and the drain region 74d. The gate stack 76, the source region 74s, and the drain region 74d may constitute a TFT.

The polycrystalline silicon layer 74 may be substituted by other material layers, for example, a SiOG layer, to which an equivalent low temperature process can be applied.

Referring to FIG. 12, an interlayer insulating layer 78 covering the TFT may be formed on the first buffer layer 72. A second buffer layer 80 may be formed on the interlayer insulating layer 78 as depicted in FIG. 12.

Referring to FIG. 13, a contact hole h1 that exposes the drain region 74d may be formed in the second buffer layer 80 and the interlayer insulating layer 78. The contact hole h1 may be formed, for example, by a photography and etching process. The contact hole h1 may be formed by other suitable methods. The contact hole h1 may be filled with a conductive plug 82 as depicted in FIG. 13.

Referring to FIG. 14, a lower electrode 84 covering the conductive plug 82 may be formed on the second buffer layer 80. The lower electrode 84 may be formed of, for example, a Pt electrode that can maintain a superior interface characteristic with a ferroelectric film, for example, a PZT film. Other suitable materials/metals may be used. A material layer that may reduce the diffusion of a dopant or may reduce a contact resistance between the lower electrode 84 and the conductive plug 82 may further be formed according to an example embodiment of the present invention.

An amorphous ferroelectric film 86 may be formed to a desired thickness on the second buffer layer 80, as shown in FIG. 14. The amorphous ferroelectric film 86 may be formed by baking and/or pre-annealing a chemical solution after coating the chemical solution that includes at least one source material sufficient for forming at least one film selected from the group consisting of a PZT film, a SBT film, a BLT film, and a BNT film. The coating process, the baking process, and/or the pre-annealing process may be performed according to example embodiments of the present invention.

A laser beam 88 may be applied to irradiate the amorphous (e.g., ferroelectric) film 86. The laser beam 88 may be a laser beam emitted from an excimer laser, for example, a laser beam having a wavelength of about 308 nm and a pulse width of about 20 ns emitted from a XeCl excimer laser. The energy density of the laser beam 88, the number of times irradiation with the laser beam is conducted, the gas atmosphere and temperature during laser beam irradiation, and the resultant change of the amorphous (e.g., ferroelectric) film 86 due to irradiation with the laser beam 88 may be the same as described in connection with the example embodiments of the present invention.

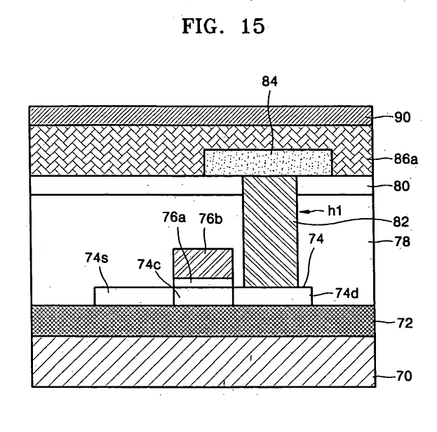

As depicted in FIG. 15, the amorphous (e.g., ferroelectric) film 86 becomes a crystal (e.g., ferroelectric) film 86a. A plate electrode 90 may be formed on the crystal ferroelectric film 86a. The plate electrode 90 may be formed of, for example, Pt to maintain a superior interface characteristic with a ferroelectric film—the same as with the lower electrode 84. The plate electrode 90 may be used as an upper electrode. In this way, according to an embodiment of FIG. 15, a semiconductor memory device that includes a transistor and a ferroelectric capacitor may be formed.

As described above, according to one or more embodiments of the present invention, an amorphous ferroelectric film may be crystallized using a XeCl excimer laser. That is, in an example embodiment of the present invention, the crystallization of the amorphous ferroelectric film may be achieved by combining a CSD method with an excimer laser irradiation method. Therefore, when an example embodiment (or suitable variations) of the present invention is used for forming a capacitor or a semiconductor memory device, the thermal deformation of other material layers formed under, for example, the ferroelectric film may be reduced (or potentially minimized) because the process for forming the ferroelectric film may be performed at a temperature lower than about 500° C. A ferroelectric film may be used in a process for manufacturing a high integration semiconductor device. Because the selective absorption of the laser beam is possible when using a ferroelectric film, mass production is possible.

While the present invention has been particularly shown and described with reference to various example embodiments thereof, the present invention should not be construed as being limited to the embodiments set forth herein. For example, one skilled in this art could apply example embodiments of the present invention to a process for forming a capacitor or a process for forming a semiconductor memory device. Also, the activation of the source and drain regions can be performed by methods other than by an irradiating laser beam in the course of forming a semiconductor memory device of a TFT. Although various example embodiments of the present invention have been shown and described, it will be understood by those of ordinary skill in the art that various changes in form and details may be made herein without departing from the spirit and scope of the present invention as defined by the following claims.

What is claimed is:

1. A method of forming a ferroelectric film, the method comprising:
preparing a substrate;
depositing an amorphous ferroelectric film on the substrate; and
crystallizing the amorphous ferroelectric film by irradiating the amorphous ferroelectric film with a laser beam.

2. The method of claim 1, wherein the depositing further includes:
coating the substrate with a chemical solution that includes a ferroelectric film source;
solidifying the chemical solution to form a solidified resultant product; and
pre-annealing the solidified resultant product.

3. The method of claim 2, wherein the pre-annealing is performed at a temperature in a range from about 500 to about 550° C.

4. The method of claim 1, wherein the laser beam is at least one of a XeCl excimer laser beam and a KrF excimer laser beam.

5. The method of claim 1, wherein the irradiating is performed under conditions sufficient to maintain the substrate at a temperature lower than about 500° C. under an oxygen or nitrogen atmosphere.

6. The method of claim 2, wherein the solidifying includes baking the solution at about 300° C. for about 5 minutes.

7. The method of claim 2, wherein the coating and the solidifying are repeated.

8. The method of claim 1, wherein the laser beam has an energy density from about 50 to about 500 mJ/cm².

9. The method of claim 8, wherein the irradiating is conducted from 1 to about 100 times.

10. The method of claim 1, wherein the amorphous ferroelectric film is at least one selected from the group consisting of a PZT film, a SBT film, a BLT film, and a BNT film.

11. A method of manufacturing a capacitor, comprising:
forming the crystallized ferroelectric film according to claim 1 on a lower electrode; and
forming an upper electrode on the crystallized ferroelectric film.

12. A method of manufacturing a semiconductor memory device comprising:
forming the crystallized ferroelectric film according to claim 1 on a lower electrode connected a TFT; and
forming an upper electrode on the crystallized ferroelectric film.

13. The method of claim 12, wherein the TFT is formed by:
forming a buffer layer on a transparent substrate;
forming an amorphous silicon layer on the buffer layer;
crystallizing the amorphous silicon layer into a polycrystalline silicon layer;
forming a polycrystalline silicon layer island by patterning the polycrystalline silicon layer;
forming a gate stack on a region of the polycrystalline silicon layer island;
doping an exposed region of the polycrystalline silicon layer island; and
activating the doped region of the polycrystalline silicon layer island.

14. The method of claim 13, wherein the doped region of the polycrystalline silicon layer island is activated by irradiating the polycrystalline silicon layer island with an excimer laser.

15. A method of forming a material film, the method comprising:
performing a chemical solution deposition of an amorphous material film at a temperature lower than 550° C.; and
irradiating the amorphous material film by irradiating with a laser beam at a temperature lower than 550° C. to form a crystalline material film.

16. The method of claim 15, wherein the amorphous material film and the crystalline material film are ferroelectric films.

17. A method of manufacturing a capacitor, comprising:
forming the crystallized ferroelectric film according to claim 16 on a lower electrode; and
forming an upper electrode on the crystallized ferroelectric film.

18. A method of manufacturing a semiconductor memory device comprising:
forming the crystallized ferroelectric film according to claim 16 on a lower electrode connected a TFT; and
forming an upper electrode on the crystallized ferroelectric film.

19. A capacitor, comprising:
a substrate;
at least one lower electrode formed on the substrate;
a crystallized ferroelectric film formed on the at least one lower electrode and the substrate; and
at least one upper electrode, formed on crystallized ferroelectric film, orthogonal to the at least one lower electrode.

20. A semiconductor memory device comprising:
the capacitor according to claim 19; and
a TFT, connected to the at least one lower electrode.
